(19) United States
(12) Patent Application Publication
(10) Pub. No.: US 2009/0189602 A1
(43) Pub. Date: Jul. 30, 2009

(54) METHOD AND APPARATUS FOR OBSERVING A MAGNETIC FIELD DECOUPLED FROM AN ELECTROMAGNETIC FIELD

(76) Inventor: RAMESH L. JOSHI, FREMONT, CA (US)

Correspondence Address: STAINBROOK & STAINBROOK, LLP, 412 AVIATION BOULEVARD, SUITE H, SANTA ROSA, CA, 95403, US

(21) Appl. No.: 12/021,522

(22) Filed: Jan. 29, 2008

(51) Int. Cl. G01R 33/02

(52) U.S. Cl. 324/246

(57) ABSTRACT

A method for observing a magnetic field decoupled from an electromagnetic field including three fundamental steps, including producing a magnetic field with an electromagnetic field producing means, maneuvering a magnetometer to observe the magnitude and delineation of said magnetic field, and observing the decoupling a magnetic field from the electromagnetic field. In a preferred embodiment the apparatus for practicing the method includes a power supply circuit for maintaining a constant direct current source. Activating the power supply causes a current to flow through the coil of a solenoid, thus creating a magnetic field inside the solenoid, preferably having a hollow low carbon steel core. The apparatus for examining the magnetic field consists of a magnetometer including a hook for hanging a specimen from a non-ferrous dowel. The system includes a ferrous specimen and a non-ferrous specimen. When current flows in the coil, the electromagnetic field turns into a (time dependent) magnetic field, while the electric field becomes zero. Maneuvering the specimen up and down in the electromagnetic field of the coil causes the ferrous specimen to rotate, while the non-ferrous specimen does not rotate.

### CROSS REFERENCES TO RELATED APPLICATIONS

Not applicable. The present application is an original and first-filed United States Utility patent application.

### STATEMENT REGARDING FEDERALLY SPONSORED RESEARCH OR DEVELOPMENT

Not applicable.

### THE NAMES OR PARTIES TO A JOINT RESEARCH AGREEMENT

Not applicable.

### INCORPORATION-BY-REFERENCE OF MATERIAL SUBMITTED ON A COMPACT DISC

Not applicable.

### BACKGROUND OF THE INVENTION

1. Field of the Invention

The apparatus of the present invention provides a way to observe a magnetic field decoupled from an electromagnetic field. A method is presented (with some of the known apparatus) to demonstrate and explain how electromagnetic phenomena is space and time dependent while a magnetic field is space dependent only, and consequently demonstrating that an electromagnetic field can produce, and/or can influence the magnetic field, but that the converse is not the case. In these apparatus, the electric field is dormant and does not participate in the experiments.

2. Discussion of Related Art Including Information Disclosed Under 37 CFR §§1.97, 1.98

Magnetic fields have been known for millennia. Current theories in physics view the magnetic and electric fields as different aspects of a single phenomenon called electromagnetism. Reducing electric and magnetic fields into a single electromagnetic field does not reveal—and on the contrary conceals—the fundamental properties and differences of these three fields. The geometrical characteristics of these fields, when experimentally observed, have completely irreconcilable orientations with respect to their surroundings, and have different space, time and matter geometrical connections.

No prior art exists that teaches or even suggests the possibility of observing a magnetic field decoupled from the electromagnetic field. The classical theory of the electromagnetic force, as set forth by James Clerk Maxwell and others, recognizes the decoupling of the electromagnetic force only as a theoretical possibility. Classical theories of electromagnetism do not yet recognize the physical possibility. For example, in his textbook on electromagnetic theory, Professor David M. Cook discusses how Maxwell's equations for the electric field and magnetic field can be manipulated and effectively equated with one another. Cook notes that the resulting equation theoretically admits the possibility of decoupling the electric and magnetic fields. However, Cook immediately refers to such events as “extraneous solutions.”

Additionally, the theory of special relativity posits the magnetic and electric fields as different aspects of the singular phenomenon of electromagnetism. (Schroeder, Daniel, Purcell Simplified, Magnetism Radiation and Relativity, talk presented at the 1999 Winter Meeting of the American Association of Physics Teachers Anaheim, Calif., 14 Jan. 1999. Also, see U.S. Pat. No. 4,414,285, to Lowry, et al).

A simple apparatus demonstrating the presence of an electromagnetic field is a galvanometer and many electrical measuring devices include a galvanometer as a basic component. It is essentially an electromechanical transducer and a practical and reliable galvanometer was built by the French physicist Jaques Arsene d'Arsonval in 1880. That instrument was modified and improved by Edward Weston in 1888, such that the widely used D′Arsonval/Weston form comprises a small pivoting coil of wire in the field of a permanent magnet. A thin pointer crossing a calibrated scale is attached to the coil and responds with a rotary deflection to the magnetic field caused by a DC current passing through the coil, thereby causing the pointer to travel across the scale and to provide an indication of the strength of the current. A torsion spring pulls the coil and pointer to the zero position. This field acts against the permanent magnet.

In this form the principal purpose of the galvanometer is to measure the current, voltage and other properties related to the current.

### BRIEF SUMMARY OF THE INVENTION

The present invention provides a method for observing a magnetic field decoupled from an electromagnetic field. The novel method utilizes a simple power circuit and a solenoid to create magnetic and electromagnetic fields. A magnetometer is then utilized to observe the boundaries and magnitude of the magnetic field produced by the solenoid. In a preferred embodiment of the invention, a horseshoe-shaped ferrous material is suspended from a string to function as the magnetometer.

The apparatus described in this invention is similar to some of the known apparatus developed by Oersted, Faraday and others, but it is devised to demonstrate discernible differences between the electromagnetic and magnetic fields, namely, that the electromagnetic field is larger than the magnetic field. The electromagnetic field can produce a magnetic field and influence it when certain geometrical constructions are carried out. It is observed that when a magnet is moved in the neighborhood of a wire (or in a coil) a current is observed in the wire (in the coil). On the other hand when a current carrying wire (or a current carrying coil) is moved in the magnetic field, the wire (coil) experiences a force, but no current is produced in the magnet. This observed phenomenon compels us to demonstrate the differences between the magnetic and electromagnetic fields. The inventive apparatus deals with the qualitative and quantitative measurements of electromagnetic and magnetic fields. The measurement criteria are function of both displacement and time consumed per displacement.

The apparatus of the present invention has theoretical and practical applications. These applications are not reported in current theoretical physics, nor are they observed in practical experiments. In this sense, the apparatus is different from a galvanometer. The apparatus theoretically reveals the influences of space, time and matter connections to the electromagnetic field. The same apparatus also reveals the practical influences of the electromagnetic field on magnetic media.

It is therefore an object of the present invention to provide a new and improved apparatus for observing a magnetic field decoupled from an electromagnetic field.

Other novel features which are characteristic of the invention, as to organization and method of operation, together with further objects and advantages thereof will be better understood from the following description considered in connection with the accompanying drawings, in which preferred embodiments of the invention are illustrated by way of example. It is to be expressly understood, however, that the drawings are for illustration and description only and are not intended as a definition of the limits of the invention. The various features of novelty that characterize the invention are pointed out with particularity in the claims annexed to and forming part of this disclosure. The invention does not reside in any one of these features taken alone, but rather in the particular combination of all of its structures for the functions specified.

There has thus been broadly outlined the more important features of the invention in order that the detailed description thereof that follows may be better understood, and in order that the present contribution to the art may be better appreciated. There are, of course, additional features of the invention that will be described hereinafter and which will form additional subject matter of the claims appended hereto. Those skilled in the art will appreciate that the conception upon which this disclosure is based readily may be utilized as a basis for the designing of other structures, methods and systems for carrying out the several purposes of the present invention. It is important, therefore, that the claims be regarded as including such equivalent constructions insofar as they do not depart from the spirit and scope of the present invention.

### BRIEF DESCRIPTION OF THE SEVERAL VIEWS OF THE DRAWINGS

The invention will be better understood and objects other than those set forth above will become apparent when consideration is given to the following detailed description thereof. Such description makes reference to the annexed drawings wherein:

FIG. 1 is a schematic diagram of the preferred embodiment of the apparatus in fully assembled configuration; and

FIG. 2 is a schematic diagram showing how an electromagnetic field includes the effect of a magnetic field.

### DETAILED DESCRIPTION OF THE INVENTION

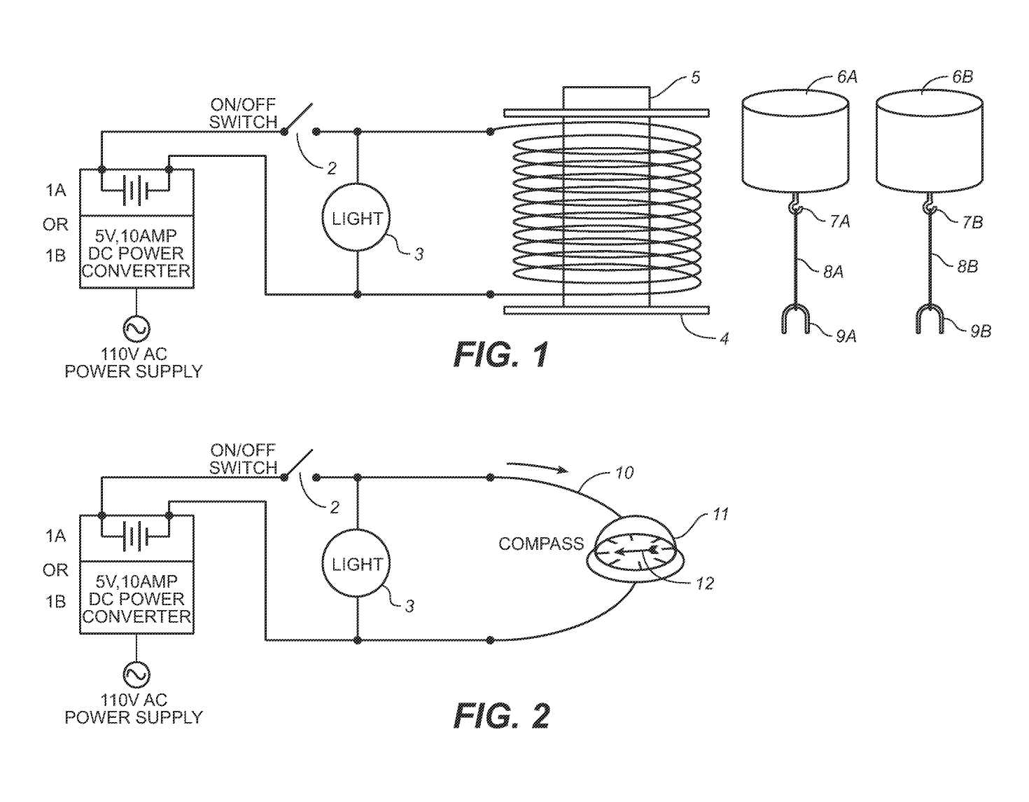

FIG. 1 is a schematic view showing a power supply circuit and an apparatus for examining the magnetic field within the solenoid portion of the power supply circuit. The power supply portion 1A or 1B of the circuit includes a power supply capable of maintaining a constant direct current source. The power supply portion of the circuit may consist of a 5 volt, 10 ampere DC converter. However, the preferred embodiment utilizes a low voltage battery that produces a high current. The power supply circuit may include a light indicator 3 and an on/off switch 2. Activating the power supply causes a current to flow through the coil of the solenoid, thus creating a magnetic field inside the solenoid.

The power supply circuit is connected to a solenoid 4. The solenoid may have a metallic core 5. In the preferred embodiment, the invention utilizes a hollow low carbon steel core. The wire coil of the solenoid must not contact the metallic core.

The apparatus for examining the magnetic field consists of a magnetometer. The preferred embodiment of the magnetometer includes a suspending means and two specimens 9A and 9B. The preferred embodiment of the suspending means constitutes a hook 7A and 7B attached to a dowel 6A and 6B. The dowel is preferably fabricated from a non-ferrous material such as wood. One specimen must consist of a ferrous material such as iron. The other specimen must consist of a non-ferrous material such as copper. The specimens may have a horseshoe shape.

In general, an electric current in a copper wire produces an electromagnetic field in its neighborhood. The electromagnetic field consists of electric and magnetic fields, which are disposed at a right angle to the direction of current or at a right angle to the conductor carrying the current. When current is flowing in the coil, the electromagnetic field turns into a (time dependent) magnetic field, while the electric field becomes zero.

Maneuvering a ferrous specimen in the electromagnetic field of the coil—converted into a magnetic field—when moved up and down on the top of the coil produces magnetic induction, which in turn, rotates the ferrous specimen. The proportionally larger magnitude of the magnetic field results in a greater magnetic induction and an increase in rotation of the ferrous specimen. In this way, the magnitude and delineation of a magnetic field can be observed with the apparatus.

Maneuvering the non-ferrous specimen up and down above the coil in the electromagnetic field of the coil—converted into a magnetic field—does not produce magnetic induction in the specimen, which in turn, does not induce rotation or other motions in the non-ferrous specimen.

If the ferrous and non-ferrous specimens are moved up and down relatively far away from the coil, though within the range of the electromagnetic field, neither specimen rotates or is otherwise caused to move by the field. The lack of induced motion in the specimens indicate that there is no induction in the non-ferrous specimen due to magnetic field, nor even in the electromagnetic field. There is no induction in the ferrous material specimen when moved in the electromagnetic filed, but it has induction in the magnetic field as produced by the electromagnetic field in the coil.

In one preferred embodiment of the invention, a 5 volt/10 Amp power supply creates a current through a solenoid with a hollow low carbon steel metallic core resulting in a magnetic field within the interior of the solenoid. The iron horseshoe specimen is suspended from the dowel. The iron horseshoe specimen is then maneuvered at the opening of the hollow solenoid core. Magnetic induction causes the iron horseshoe specimen to rotate in a manner proportional to the magnitude and location of the magnetic field. Repeating this process with a copper horseshoe specimen does not result in any rotation of the specimen due to a lack of magnetic induction. The use of the copper specimen confirms that the lack of a mechanical source for the prior observed rotation of the iron specimen.

FIG. 2 shows that the electromagnetic field includes the effect of a magnetic field. However, the magnetic field produced by the electromagnetic field is time dependent and not space dependent. We will call this magnetic field a time-magnetic field to distinguish it from the conventional magnetic field produced by unpaired electrons depending on space, which we will call a space-magnetic field. Both of these magnetic fields represent a torque with associated fields. In the foregoing consideration, we saw the effect of the space-magnet on the ferrous metal horseshoe specimen. The time magnet does not cause any motion, any effect on the ferrous horseshoe specimen. However, the time-magnet causes a magnetic needle to turn, as Oersted observed, when the needle is at a right angle to the time-magnetic field and the needle aligns with the time-magnetic field. In this motion, the principal direction of the magnetic needle aligns with the principal directions of the time-magnet, where the principal direction is along the maximum magnetic field.

The above disclosure is sufficient to enable one of ordinary skill in the art to practice the invention, and provides the best mode of practicing the invention presently contemplated by the inventor. While there is provided herein a full and complete disclosure of the preferred embodiments of this invention, it is not desired to limit the invention to the exact construction, dimensional relationships, and operation shown and described. Various modifications, alternative constructions, changes and equivalents will readily occur to those skilled in the art and may be employed, as suitable, without departing from the true spirit and scope of the invention. Such changes might involve alternative materials, components, structural arrangements, sizes, shapes, forms, functions, operational features or the like.

Therefore, the above description and illustrations should not be construed as limiting the scope of the invention, which is defined by the appended claims.

What is claimed as invention is:

1. A method for observing a magnetic field decoupled from an electromagnetic field comprising the steps of:
(a) producing a magnetic field with an electromagnetic field producing means;
(b) maneuvering a magnetometer to observe the magnitude and delineation of said magnetic field; and
(c) observing the decoupling a magnetic field from the electromagnetic field.

2. The method of claim 1, wherein step (b) involves providing a magnetometer comprising a suspending means attached to a ferrous material specimen.

3. The method of claim 1, wherein step (b) involves providing a magnetometer comprising a suspending means attached to a iron horseshoe shaped specimen

4. The method of claim 1, further including the step of observing the magnitude and delineation of space, time, and matter on the electromagnetic field.

5. The method of claim 1, for observing the magnitude and delineation of an electromagnetic field on the magnetic media, wherein said magnetic media consists of either a magnetic needle is suspended, or a ferrous metal horseshoe is suspended in front of a electromagnetic filed producing a local pole, or any (ferrous or non-ferrous) metal horseshoe is suspended in the electromagnetic field.
